(19) United States
(12) Patent Application Publication
(10) Pub. No.: US 2008/0079015 A1
(43) Pub. Date: Apr. 3, 2008

(54) OPTOELECTRONIC COMPONENT HAVING A LUMINESCENCE CONVERSION LAYER

(76) Inventor: Benjamin Claus Krummacher, Regensburg (DE)

Correspondence Address: FISH & RICHARDSON PC, P.O. BOX 1022, MINNEAPOLIS, MN, 55440-1022, US

(21) Appl. No.: 11/856,844

(22) Filed: Sep. 18, 2007

(30) Foreign Application Priority Data
Sep. 29, 2006 (DE) 10 2006 046 296.3
Nov. 2, 2006 (DE) 10 2006 051 746.6

(51) Int. Cl. H01L 33/00

(52) U.S. Cl. 257/98; 257/E33.061

(57) ABSTRACT

An optoelectronic component having an active layer that emits electromagnetic radiation when the component is on and a luminescence conversion layer disposed after said active layer in a radiation direction of said electromagnetic radiation, the luminescence conversion layer is followed in the radiation direction by a light-scattering translucent layer. The luminescence conversion layer preferably appears white owing to the light-scattering translucent layer disposed after it.

### CROSS-REFERENCE TO RELATED APPLICATIONS

This application claims the benefit of foreign priority applications filed in Germany, serial number 10 2006 046 296.3, filed Sep. 29, 2006, and serial number 10 2006 051 746.6, filed Nov. 2, 2006. The contents of the prior applications are hereby incorporated by reference in their entirety.

### TECHNICAL FIELD

The invention relates to an optoelectronic component.

### BACKGROUND

Known from the document WO 97/50132 is a radiation-emitting optoelectronic component in which at least a portion of the radiation emitted by an active layer of said optoelectronic component is converted to larger wavelengths by means of a luminescence conversion layer. In this way, for example a radiation-emitting active region that emits blue or ultraviolet light can be used to generate mixed-color or white light. As a rule, blue or ultraviolet light is converted by such a luminescence conversion layer to light of a longer wavelength, particularly to light of a complementary color, such as yellow, for example, such that the blue or ultraviolet radiation emitted by the active region is superimposed on the fraction converted to the complementary color to yield white light.

In this method of generating white light by luminescence conversion, the optical impression produced by the optoelectronic component when it is in the off state frequently is not satisfactory. The reason for this is that in a bright environment, the luminescence conversion layer is stimulated to emit yellow light even when the optoelectronic component is off, but without the superimposition of blue light to yield white light, as when it is on. As a result, in the off state, the surface of the optoelectronic component in the areas provided with the luminescence conversion layer exhibit the color of the longer wavelength produced by luminescence conversion—yellow, for example—which is often found unattractive by observers. This is particularly true in the case of relatively large-area lighting units, based, for example, on organic light-emitting diodes (OLEDs), but also in the case of LEDs or LED modules having one or more radiation-emitting semiconductor chips.

### SUMMARY

Disclosed herein is an improved optoelectronic component having a luminescence conversion layer, in which areas covered by the luminescence conversion layer give an improved color impression in the off state. The surface of the areas of the optoelectronic component covered by the luminescence conversion layer should preferably appear white in the off state.

In certain embodiments, the optoelectronic component has an active layer that emits electromagnetic radiation when the component is on and a luminescence conversion layer disposed after said active layer in a radiation direction of the electromagnetic radiation, the luminescence conversion layer is followed in the radiation direction by a light-scattering translucent layer.

The light-scattering translucent layer is transparent to the radiation that is emitted by the active layer of the optoelectronic component, which is at least partially converted by the luminescence conversion layer, such that preferably white light is able to escape from the light-scattering translucent layer when the optoelectronic component is on.

When the optoelectronic component is off, environmental light striking the surface of the light-scattering translucent layer is advantageously scattered such that the luminescence conversion layer, which is disposed behind the light-scattering translucent layer from the viewpoint of an observer, and/or additional elements of the optoelectronic component, such as for example contact layers or a surface of the active layer, can be perceived at most hazily or not at all.

The light-scattering translucent layer preferably appears white when the optoelectronic component is viewed from a direction extending oppositely to a radiation direction and the optoelectronic component is off, i.e., when the active layer is not emitting any radiation.

In a preferred embodiment, the translucent layer contains light-scattering particles to bring about the light-scattering effect. Particularly suitable for use as light-scattering particles are particles of TiO₂ or Al₂O₃, preferably having a radius of between 50 nm inclusive and 1000 nm inclusive. Alternatively, spherical or hollow-sphere-shaped particles of glass or synthetic material are also suitable.

In a further embodiment, the translucent layer has a light-scattering surface structure on a surface facing away from the active layer. The light-scattering surface structure is preferably produced by etching or sand-blasting the surface of the translucent layer.

In a preferred embodiment, the translucent layer is a glass layer. The glass layer can, for example, be glued to the luminescence conversion layer. In such a case, the adhesive preferably has high transparency to the emitted radiation in order to minimize absorption losses. Further, it is advantageous if the refractive index of the adhesive is matched to the refractive index of the light-scattering translucent layer and/or of the luminescence conversion layer to minimize reflection losses at the interface.

Alternatively, the glass layer can also be applied by means of a PVD process. In particular, the glass layer can be applied by means of a PIAD (Plasma Ion Assisted Deposition) process, since in this process the temperature at the substrate to be coated is relatively low and it is therefore possible in particular to deposit a glass layer on a heat-sensitive layer, particularly the luminescence conversion layer.

In a further preferred embodiment, the light-scattering translucent layer is a layer of synthetic material. The layer of synthetic material can in particular be applied by laminating or gluing. Alternatively, the layer of synthetic material can also be produced by spin coating, for example. In this fashion, even relatively large radiation-emitting areas, particularly large-area lighting units, can be provided with the light-scattering translucent layer with relatively little production expenditure.

The layer of synthetic material is preferably produced by means of an extruder, for example prior to laminating or gluing. It is advantageous in this case if the surface structure is created by means of a drawing-off unit of the extruder.

The thickness of the light-scattering translucent layer is advantageously selected so that it has a sufficient light-scattering effect but absorption losses in the layer are quite low. The layer thickness of the translucent layer is preferably 500 μm or less.

In a preferred embodiment, the light-scattering translucent layer is part of a common layer sequence that includes the active layer and the luminescence conversion layer. In this case, the radiation emitted by the optoelectronic component and at least partially converted by the luminescence conversion layer does not pass through an air layer, thereby reducing reflection losses, before entering the light-scattering translucent layer.

In a particularly preferred embodiment, the light-scattering translucent layer is applied directly to the luminescence conversion layer.

In a further advantageous configuration, a cladding layer is applied to the light-scattering translucent layer. The cladding layer functions in particular as a protective layer to protect the light-scattering translucent layer against mechanical damage and/or environmental influences, such as dirt or moisture, for example.

The application of a cladding layer is particularly advantageous if the light-scattering translucent layer has a light-scattering surface structure. In this case, the surface structure of the light-scattering translucent layer is advantageously planarized by the cladding layer, so that the optoelectronic component has a planar surface and the structure is protected. The cladding layer preferably has a relatively low refractive index, particularly one that is lower than or equal to the refractive index of the light-scattering translucent layer. The cladding layer thereby acts as a reflection-reducing layer. The cladding layer can, for example, contain PCS and have a refractive index of n=1.1.

The active layer of the optoelectronic component preferably contains an electroluminescent material emitting in the blue or ultraviolet region of the spectrum. The active layer can in particular contain an organic light-emitting material, preferably emitting in the blue region of the spectrum. Organic light-emitting materials are particularly suitable for the manufacture of large-area lighting units.

Alternatively, the active region of the optoelectronic component can also contain a nitride compound semiconductor material, particularly InₓAl_{y}Ga_{1-x-y}N, where 0≦x≦1, 0≦y≦1 and x+y≦1. Thus, the optoelectronic component is for example an LED or an LED module comprising one or more radiation-emitting semiconductor chips, in which case said semiconductor chip or chips emit blue or ultraviolet light that is converted to white light by the luminescence conversion layer.

The luminescence conversion layer preferably contains luminescence conversion materials that are embedded in a transparent matrix containing, for example, polycarbonate, silicone, an epoxy or PMMA.

Suitable luminescence conversion materials, such as a YAG:Ce powder, are described for example in WO 98/12757, whose content in this regard is hereby incorporated by reference.

Other features, objects, and advantages will be apparent from the following detailed description.

### DESCRIPTION OF DRAWINGS

Therein:

FIG. 1 is a schematic graphic representation of a cross section through an optoelectronic component according to a first exemplary embodiment of the invention in the on state,

FIG. 2 is a schematic graphic representation of a cross section through an optoelectronic component according to the first exemplary embodiment in the off state, and

FIG. 3 is a schematic graphic representation of a cross section through an optoelectronic component according to a second exemplary embodiment of the invention in the off state.

Like or like-acting elements are provided with the same respective reference characters in the figures. The figures are not to be considered true to scale, but rather, individual elements may be depicted as exaggeratedly large for purposes of clarification.

### DETAILED DESCRIPTION

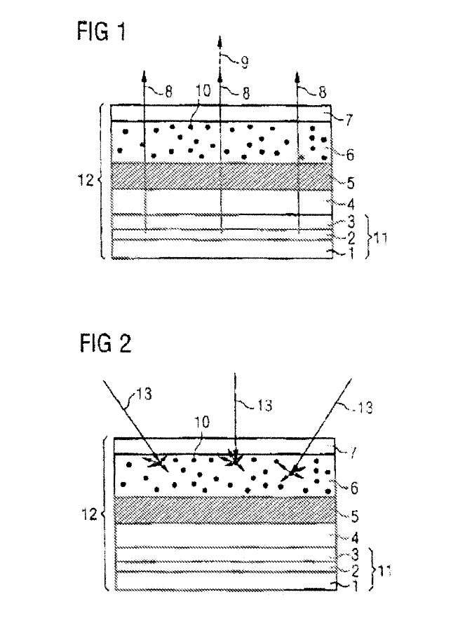

The optoelectronic component depicted in the on state in FIG. 1 and in the off state in FIG. 2 comprises an active layer 2 that emits electromagnetic radiation 8 when the optoelectronic component is on. This active layer 2 is preferably an organic light-emitting layer, particularly emitting blue light.

Alternatively, the active layer 2 can also comprise an inorganic semiconductor material, preferably emitting in the blue and/or ultraviolet region of the spectrum. The active layer 2 can in particular comprise a nitride compound semiconductor material, for example InₓAl_{y}Ga_{1-x-y}N where 0≦x≦1, 0≦y≦1 and x+y≦1.

The active layer 2 is, for example, surrounded in a layer sequence 11 by additional layers 1, 3, which serve in particular to electrically contact active layer 2 or as a growth substrate for growing active layer 2. Layer sequences 11 for radiation-emitting optoelectronic components, particularly light-emitting diodes, are known to those skilled in the art and thus will not be described in greater detail here.

Disposed after active layer 2 in a radiation direction 9 of the optoelectronic component is a luminescence conversion layer 5. Between the layer sequence 11 in which active layer 2 is located and the luminescence conversion layer 5, there is, for example, an additional layer 4, which can in particular be an encapsulating layer by means of which the layer sequence 11 is protected against environmental influences. Moreover, layer 4 can also be a passivating layer that electrically insulatingly covers electrical contacts serving to contact the active layer 2.

Alternatively, however, it is also possible for the luminescence conversion layer 5 to be applied directly to the layer sequence 11 containing the active layer 2.

At least a portion of the radiation emitted by the active layer 2 is converted by the luminescence conversion layer 5 to a longer wavelength. In particular, ultraviolet or blue radiation emitted by active layer 2 can be converted to radiation having a longer wavelength, particularly of a complementary color, such as yellow, for example, to produce white light. Luminescence conversion materials suitable for this purpose are known, for example, from the document WO 97/50132, whose disclosure content in this regard is hereby incorporated by reference. Particularly suitable are cerium-doped garnets, such as YAG:Ce, for example. Further suitable luminescence conversion materials are nitride phosphors or ionic phosphors, such as, for example, SrGa₂S₄:Eu₂⁺ or rS:Eu₂⁺. Fluorescent dyes, quantum dots or conjugated polymers are also suitable for use as luminescence conversion materials.

The luminescence conversion material of the luminescence conversion layer 5 is advantageously embedded in a transparent matrix, for example in polycarbonate, silicone, epoxy or PMMA.

The luminescence conversion layer 5 is followed in the radiation direction 9 by a light-scattering translucent layer 6. Said light-scattering translucent layer 6 is advantageously at least partially transparent to the radiation 8 emitted by active layer 2 and at least partially converted by luminescence conversion layer 5.

In this exemplary embodiment, the light-scattering translucent layer 6 contains light-scattering particles 10, which, as illustrated in FIG. 2, serve to scatter environmental light 13 striking the optoelectronic component from the outside. Such scattering particles are known, for example, in the production of frosted glass. Particularly suitable are particles of TiO₂ or Al₂O₃, preferably having a radius of between 50 nm inclusive and 1000 nm inclusive. Alternatively, spherical or hollow-sphere-shaped particles of glass or synthetic material are also suitable.

Light scattering notwithstanding, the light-scattering translucent layer 6 is at least partially transparent to the radiation 8 emitted by the active layer 2. At the same time, due to the scattering of light in light-scattering translucent layer 6, the elements located thereunder, particularly the luminescence conversion layer 5, can be perceived only hazily or not at all by an observer looking at the optoelectronic component from a direction opposite to the radiation direction 9.

Advantageously, the distribution, size and material of the light-scattering particles 10 in light-scattering translucent layer 6 are selected such that the surface of light-scattering translucent layer 6 appears white. In this way, the luminescence conversion layer 5 is advantageously prevented from exhibiting a yellowish hue, in the off state of the optoelectronic component depicted in FIG. 2, due to stimulation of the luminescence conversion materials by environmental light 13 incident from the outside.

The light-scattering translucent layer 6 can in particular be a layer of synthetic material in which light-scattering particles 10 are embedded. In the case of a layer of synthetic material, light-scattering translucent layer 6 can for example be manufactured as a film by means of an extruder and then, for example, laminated or glued onto luminescence conversion layer 5.

The light-scattering translucent layer 6 can also be a glass layer in which the light-scattering particles 10 are embedded. The glass layer can for example be glued onto the luminescence conversion layer 5.

When an adhesive is used to glue-bond a light-scattering translucent layer 6 made of a glass or a synthetic material, the refractive index of the adhesive is advantageously matched to the refractive index of the glass or of the synthetic material to prevent reflection losses.

Reflection losses are further prevented by disposing active layer 2, luminescence conversion layer 5 and light-scattering translucent layer 6 in a common layer sequence 12. As in the illustrated exemplary embodiment, the light-scattering translucent layer 6 is preferably applied directly to the luminescence conversion layer 5.

The light-scattering translucent layer 6 can also be applied to the luminescence conversion layer 5 by means of a PVD process. The PVD process used is advantageously one in which the temperature at the substrate to be coated, for example luminescence conversion layer 5, is relatively low. A PIAD (Plasma Ion Assisted Deposition) process is particularly suitable for this purpose.

The layer thickness of the light-scattering translucent layer 6 is preferably 500 μm or less. This is particularly advantageous if the active layer 2 is an organic light-emitting layer applied to a flexible substrate, since, due to its relatively small thickness, the light-scattering translucent layer 6 comprised in the layer sequence 12 will not substantially reduce the flexibility of the optoelectronic component.

A cladding layer 7 is preferably applied to light-scattering translucent layer 6. Said cladding layer 7 advantageously has a refractive index the value of which is between the refractive index of the surrounding medium, especially air, and that of light-scattering translucent layer 6. In this way, the cladding layer 7 functions as a reflection-reducing layer for the environmental light 13 striking the optoelectronic component from the outside. In addition, the cladding layer 7 can advantageously serve to protect the light-scattering translucent layer 6 and the layers thereunder.

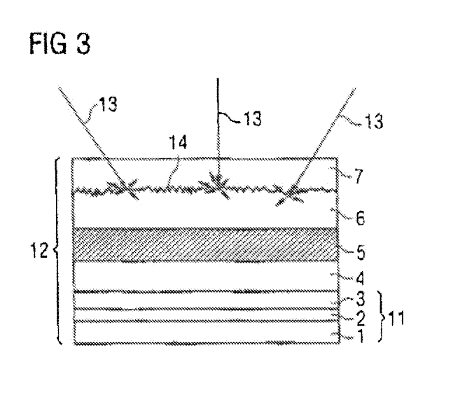

The second exemplary embodiment of the optoelectronic component, which is illustrated in FIG. 3, differs from the exemplary embodiment depicted in FIGS. 1 and 2 with regard to the implementation of light-scattering translucent layer 6. In this exemplary embodiment, the light-scattering translucent effect is achieved, not with light-scattering particles, but by means of a light-scattering surface structure 14 formed on a surface of light-scattering translucent layer 6.

For example, light-scattering translucent layer 6 can be a glass layer whose surface is treated by an etching process or sand-blasting to produce the light-scattering surface structure 14.

Alternatively, the light-scattering translucent layer 6 can also be a layer of synthetic material with a light-scattering surface structure created on its surface. For example, the layer of synthetic material can be produced by an extrusion process, in which case it can advantageously be structured even as it is being extruded. This can be done by having the light-scattering structure 14 be produced by a drawing-off unit on the extruder.

The structured layer of glass or synthetic material acting as the light-scattering translucent layer can be provided with a cladding layer 7 to planarize the surface structure. The optoelectronic component thus advantageously has a planar surface. The cladding layer 7 also advantageously protects the surface structure created in the light-scattering translucent layer 6 against environmental influences, such as dirt or moisture, for example, and against mechanical damage.

The second exemplary embodiment, illustrated in FIG. 3, is otherwise the same as the first exemplary embodiment, illustrated in FIGS. 1 and 2.

The variant implementations of the light-scattering translucent layer 6 represented in the two exemplary embodiments can also be combined with one another. Thus, the light-scattering translucent layer 6 can comprise both light-scattering particles 10 and a light-scattering surface structure 14. This increases the scattering of light.

The invention is not limited by the description with reference to the exemplary embodiments. Rather, the invention encompasses any novel feature and any combination of features, including in particular any combination of features recited in the claims, even if that feature or combination itself is not explicitly mentioned in the claims or exemplary embodiments.

Additional embodiments are within the scope of the following claims.

What is claimed is:

1. An optoelectronic component having an active layer that emits electromagnetic radiation when said component is on and a luminescence conversion layer disposed after said active layer in a radiation direction of said electromagnetic radiation,
wherein said luminescence conversion layer is followed in said radiation direction by a light-scattering translucent layer.

2. The optoelectronic component as in claim 1,
wherein said light-scattering translucent layer appears white when said optoelectronic component is off.

3. The optoelectronic component as in claim 1,
wherein said light-scattering translucent layer contains light-scattering particles.

4. The optoelectronic component as in claim 3,
wherein said light-scattering particles contain Al₂O₃ or TiO₂.

5. The optoelectronic component as in claim 3,
wherein said light-scattering particles have a radius of between 50 nm inclusive and 1000 nm inclusive.

6. The optoelectronic component as in claim 3,
wherein said light-scattering particles are spheres or hollow spheres made of a glass or a synthetic material.

7. The optoelectronic component as in claim 1,
wherein said light-scattering translucent layer has a light-scattering surface structure on a surface facing away from said active layer.

8. The optoelectronic component as in claim 7,
wherein said light-scattering surface structure is created by etching or sand-blasting.

9. The optoelectronic component as in claim 1,
wherein said light-scattering translucent layer is a glass layer.

10. The optoelectronic component as in claim 9,
wherein said glass layer is glued onto the component.

11. The optoelectronic component as in claim 9,
wherein said glass layer is applied to the component by means of a PVD process.

12. The optoelectronic component as in claim 1,
wherein said light-scattering translucent layer is a layer of synthetic material.

13. The optoelectronic component as in claim 12,
wherein said layer of synthetic material is produced by means of an extrusion process.

14. The optoelectronic component as in claim 12,
wherein said layer of synthetic material is laminated on or glued on to the component.

15. The optoelectronic component as in claim 1,
wherein a layer thickness of said light-scattering translucent layer is 500 μm or less.

16. The optoelectronic component as in clam 1,
wherein said light-scattering translucent layer is comprised in a layer sequence that includes said active layer and said luminescence conversion layer.

17. The optoelectronic component as in claim 1,
wherein said light-scattering translucent layer is applied directly to said luminescence conversion layer.

18. The optoelectronic component as in claim 1,
wherein a cladding layer is applied to said light-scattering translucent layer.

19. The optoelectronic component as in claim 1,
wherein during the operation of said optoelectronic component, said active layer emits blue or ultraviolet radiation that is converted to white light by said luminescence conversion layer.

20. The optoelectronic component as in claim 1,
wherein said active layer contains an organic light-emitting material.

21. The optoelectronic component as in claim 1,
wherein said active layer contains a nitride compound semiconductor material.
